(19) United States
(12) Patent Application Publication
(10) Pub. No.: US 2016/0211250 A1
(43) Pub. Date: Jul. 21, 2016

(54) SEMICONDUCTOR SUBSTRATE ARRANGEMENT, A SEMICONDUCTOR DEVICE, AND A METHOD FOR PROCESSING A SEMICONDUCTOR SUBSTRATE

(71) Applicant: Infineon Technologies AG, Neubiberg (DE)

(72) Inventors: Wolfram LANGHEINRICH, Dresden (DE); Robert STRENZ, Radebeul (DE); Georg TEMPEL, Dresden (DE); Knut STAHRENBERG, Dresden (DE); Nikolaos HATZOPOULOS, Dresden (DE); Christoph BUKETHAL, Dresden (DE); Klaus KNOBLOCH, Dresden (DE); Achim GRATZ, Dresden (DE); Mayk ROEHRICH, Dresden (DE)

(21) Appl. No.: 14/597,342

(22) Filed: Jan. 15, 2015

(51) Int. Cl. H01L 27/02; H01L 29/16; H01L 29/49; H01L 27/12; H01L 27/115

(52) U.S. Cl. CPC H01L 27/0207; H01L 27/1207; H01L 27/11521; H01L 29/4925; H01L 29/16; H01L 27/11568

(57) ABSTRACT

According to various embodiments, a semiconductor substrate arrangement may be provided, wherein the semiconductor substrate arrangement may include: a semiconductor substrate defining a first area at a first level and a second area next to the first area at a second level, wherein the first level is lower than the second level; a plurality of planar non-volatile memory structures disposed over the semiconductor substrate in the first area; and a plurality of planar transistor structures disposed over the semiconductor substrate in the second area.

### TECHNICAL FIELD

Various embodiments relate generally to a semiconductor substrate arrangement, a semiconductor device, and a method for processing a semiconductor substrate.

### BACKGROUND

In general, a semiconductor substrate, e.g. a chip, a die, a wafer or any other type of semiconductor work piece, may be processed in semiconductor technology to provide one or more integrated circuit structures on and/or in the semiconductor substrate. The semiconductor substrate may have a main processing surface, also referred to as front side, wherein the one or more integrated circuit structures may be formed at the main processing surface during semiconductor processing. The integrated circuit structures provided on and/or in the semiconductor substrate may include a plurality of non-volatile memory structures and a plurality of transistors, e.g. for controlling the plurality of non-volatile memory structures. The plurality of non-volatile memory structures may be operated at high voltages, e.g. at a voltage greater than about 6 V, e.g. during writing and/or erasing the non-volatile memory structures, while the plurality of transistors may be operated at low voltages, e.g. at a voltage less than about 6 V. The non-volatile memory structures may be provided in so called NVM-areas or memory-areas on a semiconductor substrate and the plurality of transistors, also referred to as logic or logic integrated circuits, may be provided in logic-areas on the semiconductor substrate. The plurality of transistors for the logic may be provided in complementary metal-oxide-semiconductor technology (CMOS).

### SUMMARY

According to various embodiments, a semiconductor substrate arrangement may be provided, wherein the semiconductor substrate arrangement may include: a semiconductor substrate defining a first area at a first level and a second area next to the first area at a second level, wherein the first level is lower than the second level; a plurality of planar non-volatile memory structures disposed over the semiconductor substrate in the first area; and a plurality of planar transistor structures disposed over the semiconductor substrate in the second area.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a semiconductor substrate in a schematic top view, according to various embodiments;

FIG. 1B shows the semiconductor substrate illustrated in FIG. 1A in a schematic cross sectional view, according to various embodiments;

FIGS. 1C to 1E show a semiconductor substrate arrangement respectively in a schematic cross sectional view, according to various embodiments;

FIGS. 2A to 2C show a method for processing a semiconductor substrate respectively in a schematic flow diagram, according to various embodiments;

FIG. 3A shows a non-volatile memory structure of a semiconductor substrate arrangement in a schematic cross sectional view, according to various embodiments;

FIGS. 3B to 3D show a transistor structure of a semiconductor substrate arrangement respectively in a schematic cross sectional view, according to various embodiments; and

FIGS. 4A to 4H show a semiconductor substrate arrangement respectively at various stages during processing in a schematic cross sectional view, according to various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

The term “lateral” used with regards to the “lateral” extension of a structure (or of a structure element) provided at least one of on or in a carrier (e.g. a substrate, a wafer, or a semiconductor work piece) or “laterally” next to, may be used herein to mean an extension or a positional relationship along a surface of the carrier. That means that a surface of a carrier (e.g. a surface of a substrate, a surface of a wafer, or a surface of a work piece) may serve as reference, commonly referred to as the main processing surface. Further, the term “width” used with regards to a “width” of a structure (or of a structure element) may be used herein to mean the lateral extension of a structure. Further, the term “height” used with regards to a height of a structure (or of a structure element), may be used herein to mean an extension of a structure along a direction perpendicular to the surface of a carrier (e.g. perpendicular to the main processing surface of a carrier). The term “thickness” used with regards to a “thickness” of a layer may be used herein to mean the spatial extension of the layer perpendicular to the surface of the support (the material or material structure) on which the layer is deposited. If a surface of the support is parallel to the surface of the carrier (e.g. parallel to the main processing surface) the “thickness” of the layer deposited on the surface of the support may be the same as the height of the layer. Further, a “vertical” structure may be referred to as a structure extending in a direction perpendicular to the lateral direction (e.g. perpendicular to the main processing surface of a carrier) and a “vertical” extension may be referred to as an extension along a direction perpendicular to the lateral direction (e.g. an extension perpendicular to the main processing surface of a carrier).

According to various embodiments, a non-volatile memory (NVM) cell, e.g. a split gate NVM cell, may be integrated into a CMOS technology, e.g. into a gate-last high-K metal gate process, as for example established in the 28 nm (or less than 28 nm) CMOS node. According to various embodiments, a single chip may be provided including high performance logic transistors in a logic area of the chip and with an NVM array in an NVM area if the chip, wherein the NVM area fulfills highest reliability requirements.

Illustratively, in semiconductor technology, the feature size for logic transistors is steadily reduced, wherein for example a respective scaling of an NVM cell (e.g. a so called split gate FLASH memory cell) may be difficult while retaining the reliability.

According to various embodiments, one or more NVM cells may be provided herein on the same chip as one or more high-K metal gate transistors, wherein the one or more NVM cells have a high reliability, e.g. a particular cycle ability and/or long term stability, and a well-established error detection. Further, the one or more high-K metal gate transistors may be formed in gate-last processing. Therefore, the respective thicknesses of the layers of an NVM cell, e.g. provided in planar technology, may be adapted with respect to the desired reliability of the NVM cell and may be formed independently of the logic transistors provided on the same chip. The logic transistors instead may be formed with respect to the desired performance. To provide the one or more high-K metal gate transistors in gate-last processing, at least one planarization (e.g. chemical mechanical polishing) may be required, wherein the semiconductor substrate may be adapted to provide conditions so that the planarization may not affect the one or more NVM cells.

According to various embodiments, one or more transistor structures (e.g. planar transistor structures based on at least one layer stack respectively) may be provided herein on the same chip as one or more high-K metal gate transistors. The transistor structure may include (or may be at least part of) a high voltage transistor (e.g. a transistor which can be operated at a voltage of greater than about 6 V). Further, the one or more high-K metal gate transistors may be formed in gate-last processing. To provide the one or more high-K metal gate transistors in gate-last processing, at least one planarization (e.g. chemical mechanical polishing) may be required, wherein the semiconductor substrate may be adapted to provide conditions so that the planarization may not affect the one or more transistor structures. According to various embodiments, the respective thicknesses of the at least one layer stack of the one or more transistor structures, e.g. provided in planar technology, may be greater than the respective thicknesses of the high-K metal gate transistors.

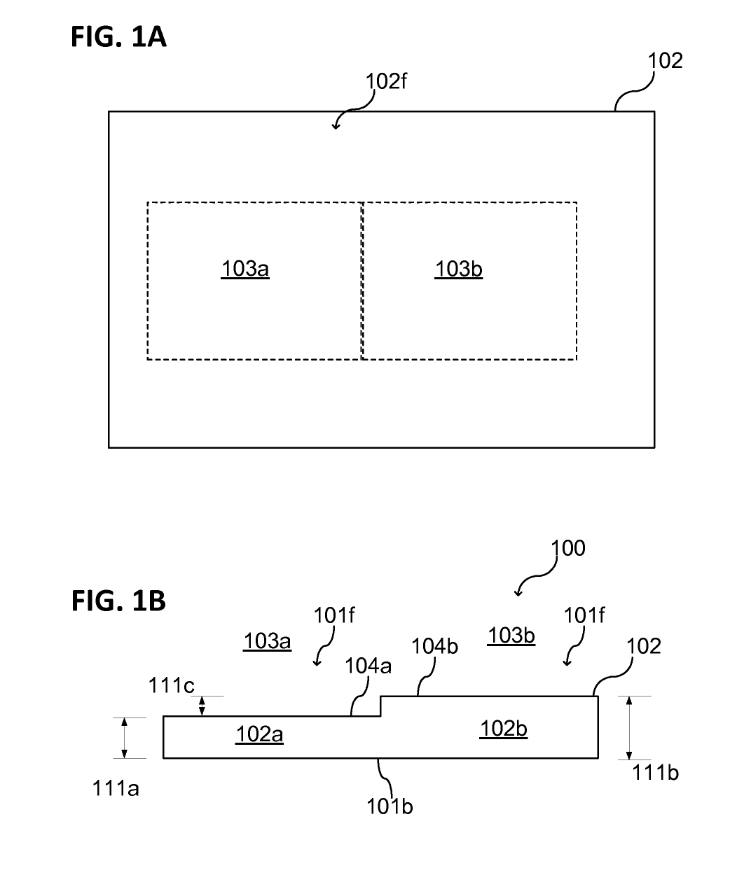

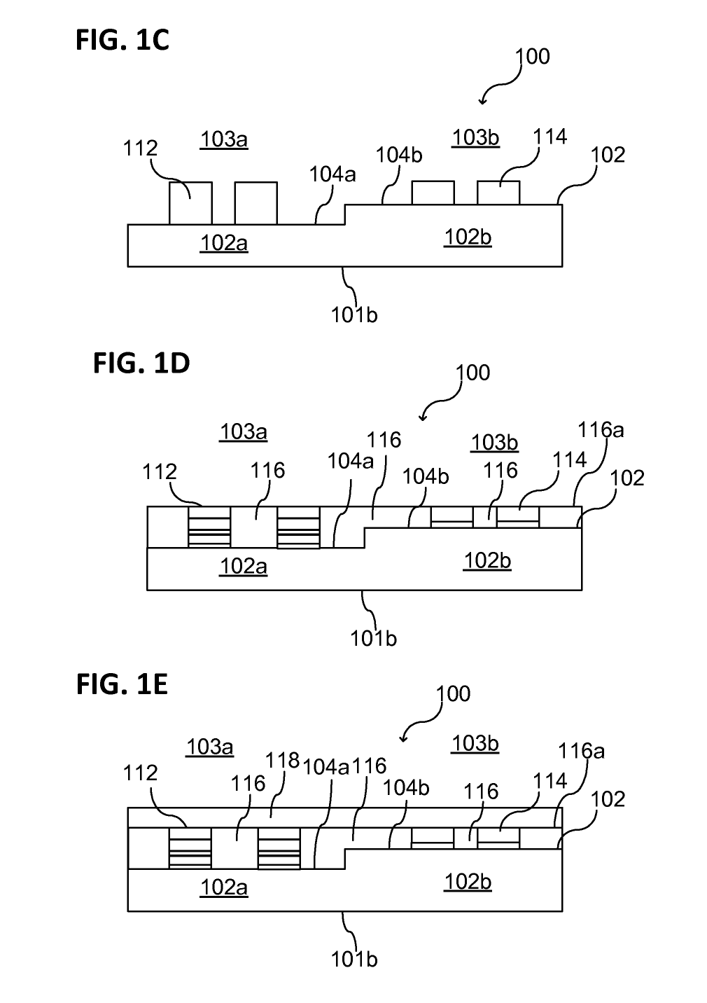

FIG. 1A shows a semiconductor substrate 102 in a schematic top view, according to various embodiments. The semiconductor substrate 102 may have a main processing surface 102f, wherein the main processing surface 102f may define, for example, a front side 101f (cf. FIG. 1B). The semiconductor substrate 102 may be or may be at least part of a semiconductor wafer, a semiconductor die, a semiconductor chip or any other semiconductor work piece processable in semiconductor technology. According to various embodiments, the semiconductor substrate 102 may be made of or may include semiconductor materials of various types, including, for example, silicon, germanium, Group III to V or other types, including polymers, for example, although in another embodiment, other suitable materials can also be used. In an embodiment, the semiconductor substrate 102 is made of silicon (doped or undoped), in an alternative embodiment, the semiconductor substrate 102 is a silicon on insulator (SOI) wafer. As an alternative, any other suitable semiconductor materials can be used for the semiconductor substrate 102, for example semiconductor compound material such as gallium arsenide (GaAs), indium phosphide (InP), but also any suitable ternary semiconductor compound material or quaternary semiconductor compound material such as indium gallium arsenide (InGaAs). According to various embodiments, the semiconductor substrate 102 may be a thin or an ultrathin substrate or wafer, e.g. with a thickness in the range from about several micrometers to about several tens of micrometers, e.g. in the range from about 5 μm to about 50 μm, e.g. with a thickness less than about 100 μm or less than about 50 μm. According to various embodiments, a semiconductor substrate 102 may include SiC (silicon carbide) or may be a silicon carbide substrate 102, e.g. a silicon carbide wafer 102.

According to various embodiments, the semiconductor substrate 102 may define at least a first area 103a, e.g. at least one so called NVM area for accommodating a plurality of non-volatile memory structures; and a second area 103b next to the first area, e.g. at least one so called logic area for accommodating a plurality of transistor structures, e.g. logic transistors in CMOS technology.

According to various embodiments, in case the semiconductor substrate 102 is a semiconductor wafer 102, the semiconductor wafer 102 may include a plurality of chip regions, wherein each chip region may define at least a first area 103a and a second area 103b. According to various embodiments, in case the semiconductor substrate 102 is a semiconductor chip or a semiconductor die 102, the semiconductor chip or the semiconductor die 102 may define at least one first area 103a and at least one second area 103b. The two areas 103a, 103b may be adjacent to each other or may be spaced apart from each other. According to various embodiments, the first area 103a may extend over more than 20% the main processing surface 102f of the semiconductor substrate. According to various embodiments, the second area 103b may extend over more than 20% of the main processing surface 102f of the semiconductor substrate. According to various embodiments, the first area 103a may extend over more than 20% of the front side chip area 102f of a chip or die 102. According to various embodiments, the second area 103b may extend over more than 20% of the front side chip area 102f of a chip or die 102.

FIG. 1B shows the semiconductor substrate 102, e.g. as illustrated in FIG. 1A, in a schematic cross sectional view, according to various embodiments. The first area 103a may be defined by a first region 102a of the semiconductor substrate 102, wherein a plurality of NVM cells may be provided at least one of over or in the first region 102a. The second area 103b may be defined a second region 102b of the semiconductor substrate 102, wherein a plurality of logic transistors may be provided at least one of over or in the second region 102b.

According to various embodiments, the semiconductor substrate 102 may have a first level 104a in the first area 103a (illustratively a first height level perpendicular to the lateral extension of the semiconductor substrate 102) for accommodating the plurality of non-volatile memory structures; and a second level 104b in the second area 103b (illustratively a second height level perpendicular to the lateral extension of the semiconductor substrate 102) for accommodating the plurality of transistor structures. According to various embodiments, the first level 104a may be lower than the second level 104b. Illustratively, the main processing surface 102f of a semiconductor substrate 102 may have at least one step 111c or the semiconductor substrate 102 may be processed to provide a stepwise main processing surface 102f. According to various embodiments, the semiconductor substrate 102 may have a planar (in other words a flat) backside 101b or may be plane (in other words flat) at the backside 101b.

According to various embodiments, as illustrated in FIG. 1B, both levels 104a, 104b may be planar (in other words flat) and parallel to each other. The first region 102a of the semiconductor substrate 102 (e.g. defining the first area 103a) may have a first thickness 111a and the second region 102b of the semiconductor substrate 102 (e.g. defining the second area 103b) may have, for example, a second thickness 111b greater than the first thickness 111a. The difference between the second thickness 111b and the first thickness 111a may be regarded as step height 111c. According to various embodiments, the first thickness 111a and the second thickness 111b may be for example in the range from about 5 μm to about 1 mm, or greater than 1 mm or less than 5 μm. According to various embodiments, the step height 111c may be in the range from about 5 nm to about 1 μm, e.g. in the range from about 5 nm to about 100 nm, e.g. in the range from about 10 nm to about 60 nm. According to various embodiments, the step height 111c may be selected so that the plurality of NVM cells (or the plurality of any other transistor structures) in the first area 103a may be disposed low enough to process the plurality of transistors in the second area 103b without damaging and/or affecting the plurality of NVM cells (or the plurality of any other transistor structures) in the first area 103a.

According to various embodiments, the semiconductor substrate 102 may include a buried oxide layer (e.g. a buried silicon oxide layer) in the second area 103b. In this case, the semiconductor substrate 102 may be free from the buried oxide layer in the first area 103a. Illustratively, the step height 111c from the first level 104a to the second level 104b may be provided by partially removing the silicon top layer of a silicon on insulator substrate and, e.g. optionally, partially removing the insulator layer of a silicon on insulator substrate in the first area 103a. Alternatively, the step height 111c from the first level 104a to the second level 104b may be provided by depositing semiconductor material over the semiconductor substrate 102 in the second area 103b, e.g. by epitaxially growing semiconductor material (e.g. silicon) on the semiconductor substrate 102 in the second area 103b.

According to various embodiments, the semiconductor substrate 102 may include desired doping profiles, e.g. lightly doped regions (e.g. lightly doped drain, LDD, regions) and/or highly doped regions (e.g. highly doped drain, HDD, regions) with p-type or n-type doping respectively. Further the semiconductor substrate 102 may include p-type or n-type doped well regions.

FIG. 1C shows a semiconductor substrate arrangement 100 in a schematic cross sectional view, according to various embodiments. The semiconductor substrate arrangement 100 may include or may be a chip, a die, a wafer, or any other semiconductor device.

According to various embodiments, the semiconductor substrate arrangement 100 may include a semiconductor substrate 102, as described before, e.g. referring to FIG. 1A and FIG. 1B. Further, the semiconductor substrate arrangement 100 may include a plurality of non-volatile memory structures 112 (e.g. NVM cells in planar technology) disposed over the semiconductor substrate 102 in the first area 103a (e.g. formed at least one of over or in the first region 102a of the semiconductor substrate 102); and a plurality of transistor structures 114 (e.g. logic transistors in planar technology) disposed over the semiconductor substrate 102 in the second area 103b (e.g. formed at least one of over or in the second region 102b of the semiconductor substrate 102).

According to various embodiments, the non-volatile memory structures 112 may include or may be at least one of the following: a silicon-oxide-nitride-oxide-silicon (SONOS) NVM, e.g. with silicon nitride as charge storage material, a silicon-high-K-nitride-oxide-silicon (SHINOS) NVM, a split-gate NVM, e.g. including polysilicon as charge storage material, or any other type of NVM structure or NVM device, e.g. non-volatile random-access memory (NVRAM), flash memory, erasable programmable read only memory (EPROM), electrically erasable programmable read-only memory (EEPROM), phase-change memory, magneto resistive random-access memory, ferroelectric random-access memory, floating junction gate random-access memory. According to various embodiments, the non-volatile memory structures 112 may include or may be planar layer-stack based memory structures.

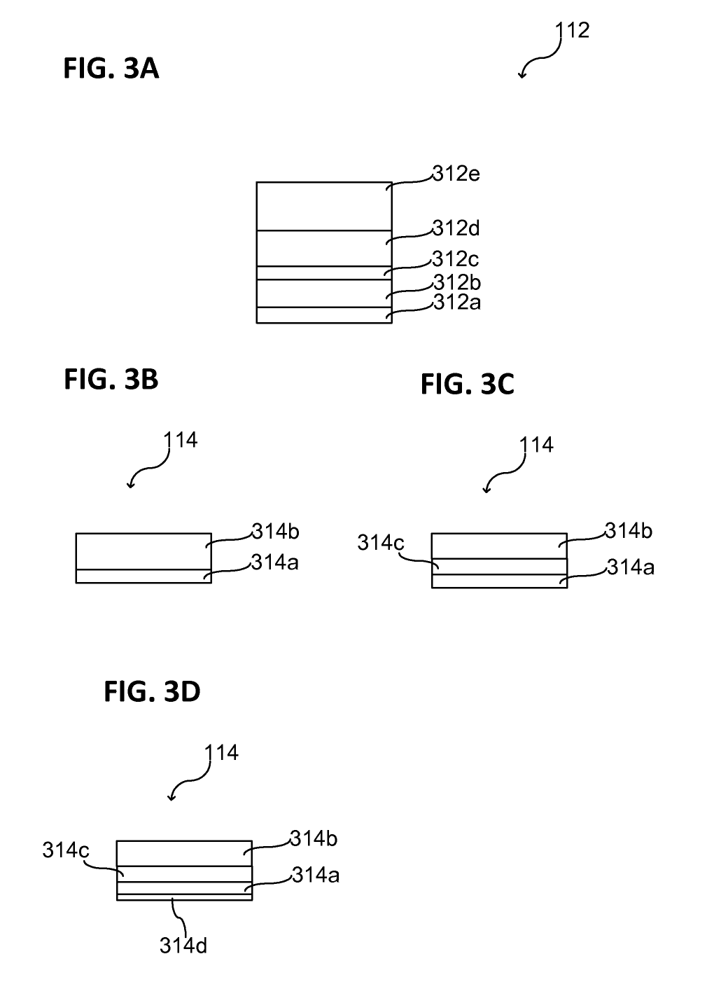

According to various embodiments, the non-volatile memory structures 112 may be provided in planar technology, e.g. including a layer stack, wherein the layer stack may include a charge storage layer and a control gate layer disposed over the charge storage layer. The charge storage layer may be separated from the control gate layer by one or more dielectric layers (e.g. electrically insulating layers, e.g. oxide layers and/or nitride layers), cf. for example FIG. 3A. According to various embodiments, the charge storage layer and the control gate layer may extend into the lateral direction.

Further, according to various embodiments, the transistor structures 114 may include field effect transistors structures. The transistor structures 114 may be provided in planar technology, e.g. including a layer stack, wherein the layer stack may include a dielectric gate isolation layer and an electrically conductive gate layer disposed over the gate isolation layer, cf. FIGS. 3B to 3D. According to various embodiments, the dielectric gate isolation layer and the electrically conductive gate layer may extend into the lateral direction. According to various embodiments, each of the transistor structures 114 may be at least part of any type of transistor processable in semiconductor technology, e.g. of a field effect transistor, e.g. of a field effect transistor with a high-K gate isolation layer and a metal gate layer disposed over the high-K gate isolation layer.

According to various embodiments, a high-K (also referred to as high-κ or high-∈ᵣ) material may be any suitable material having a dielectric constant κ (also referred to as ∈ᵣ and/or relative permittivity) greater than silicon dioxide (∈ᵣ=3.9) or greater than any of the silicon oxynitrides (∈ᵣ<6). According to various embodiments, a high-K material may include at least one transition metal oxide (e.g. Ta₂O₅ HfO₂, ZrO₂) and/or at least one rare earth metal oxide (e.g. Pr₂O₃, Gd₂O₃ and Y₂O₃), or any other metal oxide, e.g. aluminum oxide, having for example dielectric constant greater than or equal to about 9.

FIG. 1D shows a semiconductor substrate arrangement 100 in a schematic cross sectional view, according to various embodiments, wherein the semiconductor substrate arrangement 100 includes a semiconductor substrate 102 defining a first area 103a at a first level 104a and a second area 103b next to the first area 103a at a second level 104b, wherein the first level 104a is lower than the second level 104b; and a plurality of planar non-volatile memory structures 112 disposed over the semiconductor substrate 102 in the first area 103a; and a plurality of planar transistor structures 114 disposed over the semiconductor substrate 102 in the second area 103b.

According to various embodiments, each of the plurality of planar non-volatile memory structures 112 has a first height and each of the plurality of planar transistor structures 114 has a second height, wherein the second height is less than the first height. Therefore, the semiconductor substrate 102 may compensate the different heights of the planar non-volatile memory structures 112 and the planar transistor structures 114. Further, the space between the planar non-volatile memory structures 112 and the planar transistor structures 114 may be filled with an interlayer dielectric (ILD) 116, e.g. with an oxide interlayer dielectric, e.g. with a glass, e.g. with borosilicate glass. According to various embodiments, the interlayer dielectric 116 may be a low-K dielectric material.

As illustrated in FIG. 1D, the semiconductor substrate arrangement 100 including the planar non-volatile memory structures 112 and the planar transistor structures 114 may be planarized, e.g. at the front side. Further, an additional layer 118 may be disposed over the plurality of planar non-volatile memory structures 112 and the plurality of planar transistor structures 114 (e.g. and over the dielectric material 116), wherein the additional layer 118 has a planar interface plane facing the plurality of planar non-volatile memory structures 112 and the plurality of planar transistor structures 114, as illustrated for example in FIG. 1E in a schematic cross sectional view of the semiconductor substrate arrangement 100, according to various embodiments.

The additional layer may include at least one of a passivation layer or a metallization layer. The additional layer may include the wiring for electrically connecting and/or contacting the plurality of planar non-volatile memory structures 112 and the plurality of planar transistor structures 114.

Further, (not illustrated) the semiconductor substrate arrangement 100 may include a plurality of first trench isolation structures in the first area 103a extending into the semiconductor substrate 102 for laterally electrically isolating the plurality of planar non-volatile memory structures 112 from each other and a plurality of second trench isolation structures in the second area 103b extending into the semiconductor substrate with a second depth for laterally electrically isolating the plurality of planar transistor structures 114 from each other.

Since the non-volatile memory structures 112 may be operated at higher voltages than the transistor structures 114, the first depth of the first trench isolation structures may be greater than the second depth of the second trench isolation structures. According to various embodiments, the trench isolation structures may be shallow trench isolation (STI) structures.

Further (not illustrated) the semiconductor substrate arrangement 100 may include a plurality of first source regions and a plurality of first drain regions in the first region 102a of the semiconductor substrate 102 in the first area 103a for operating the plurality of planar non-volatile memory structures 112 and a plurality of second source regions and a plurality of second drain regions in the second region 102b of the semiconductor substrate 102 in the second area 103b for operating the plurality of planar transistor structures 114.

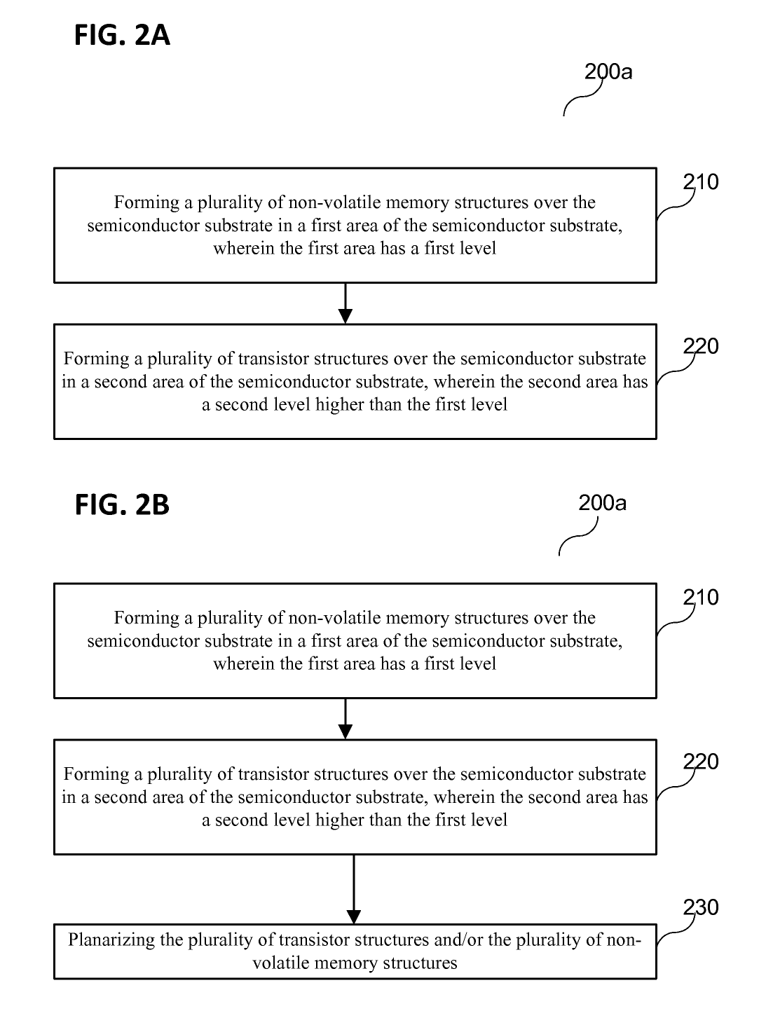

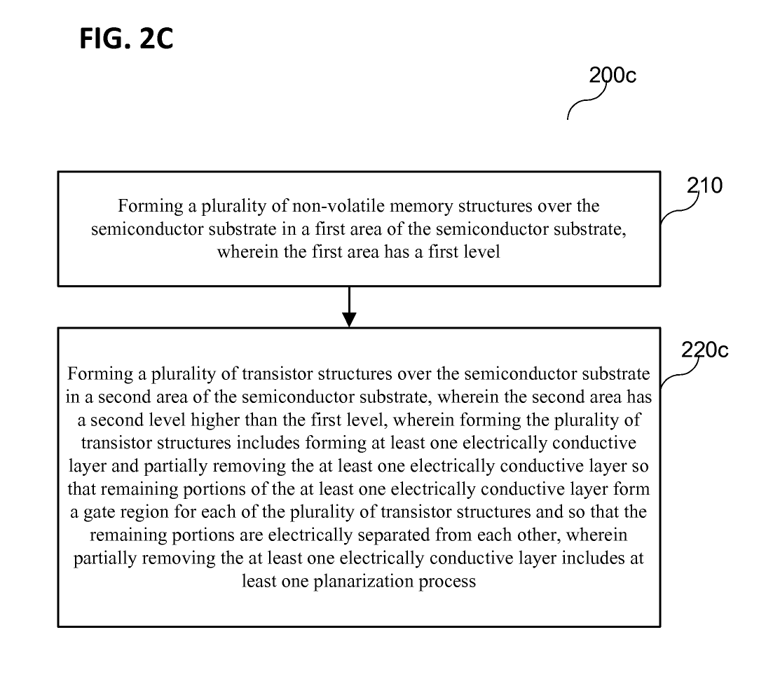

FIG. 2A shows a method 200a for processing a semiconductor substrate in a schematic flow diagram, according to various embodiments, wherein the method 200a may include: in 210, forming a plurality of non-volatile memory structures 112 over the semiconductor substrate 102 in a first area 103a defined by the semiconductor substrate 102, wherein the first area 103a has a first level 104a; and, in 220, forming a plurality of transistor structures 114 over the semiconductor substrate 102 in a second area 103b defined by the semiconductor substrate 102, wherein the second area 103b has a second level 104b higher than the first level 103a.

FIG. 2B shows a method 200b for processing a semiconductor substrate in a schematic flow diagram, according to various embodiments, wherein the method 200b may include: in 210, forming a plurality of non-volatile memory structures 112 over the semiconductor substrate 102 in a first area 103a defined by the semiconductor substrate 102, wherein the first area 103a has a first level 104a; in 220, forming a plurality of transistor structures 114 over the semiconductor substrate 102 in a second area 103b defined by the semiconductor substrate 102, wherein the second area 103b has a second level 104b higher than the first level 103a; and, in 230, planarizing the plurality of transistor structures 114 and/or the plurality of non-volatile memory structures 112.

According to various embodiments, the planarizing may be for example part of the processing of the plurality of transistor structures 114, e.g. if the transistor structures 114 include high-K metal gate transistors formed in gate-last processing. Further, according to various embodiments, the plurality of non-volatile memory structures 112 may not be damaged or affected by the planarizing. Further, the plurality of non-volatile memory structures 112 may be readily processed before the planarizing is carried out.

According to various embodiments, planarizing may include chemical mechanical polishing (CMP).

According to various embodiments, forming the plurality of non-volatile memory structures 112 may include high temperature processes, e.g. at a temperature greater than about 500° C. Such a high temperature processes may affect the transistor structures 114. Therefore, the plurality of non-volatile memory structures 112 may be readily processed before the functioning transistor structures 114 are formed in the second area 103b of the semiconductor substrate 102.

According to various embodiments, forming the plurality of non-volatile memory structures 104 may include forming a plurality of first layer stacks 112, as for example illustrated in FIG. 1D, each of the first layer stacks 112 may include a charge storage layer and a control gate layer disposed over the charge storage layer. Further, forming the plurality of transistor structures 114 may include forming a plurality of second layer stacks 114, as for example illustrated in FIG. 1D, each of the second layer stacks 114 may include a dielectric gate isolation layer and a metal gate layer disposed over the gate isolation layer. According to various embodiments, the first layer stacks 112 may be formed before the second layer stacks 114 are formed.

FIG. 2C shows a method 200c for processing a semiconductor substrate in a schematic flow diagram, according to various embodiments, wherein the method 200c may include: in 210, forming a plurality of non-volatile memory structures over the semiconductor substrate in a first area defined by the semiconductor substrate, wherein the first area has a first level; and, in 220c, forming a plurality of transistor structures over the semiconductor substrate in a second area defined by the semiconductor substrate, wherein the second area has a second level higher than the first level, wherein forming the plurality of transistor structures includes forming at least one electrically conductive layer (e.g. at least in the second area) and partially removing the at least one electrically conductive layer so that remaining portions of the at least one electrically conductive layer form a gate region for each of the plurality of transistor structures and so that the remaining portions are electrically separated from each other, wherein partially removing the at least one electrically conductive layer includes at least one planarization process.

According to various embodiments, the at least one electrically conductive layer may be at least one metal layer. Illustratively, a plurality of high-K metal gate transistors may be formed by at least one planarization process, e.g. by at least one CMP process. According to various embodiments, the planarization process may form a flat top surface in the first area and in the second area.

According to various embodiments, forming the plurality of transistor structures may further include forming a high-K dielectric layer (e.g. at least in the second area), e.g. disposed below the at least one metal layer, and partially removing the high-K dielectric layer so that remaining portions of the high-K dielectric layer form a gate isolation for each of the plurality of transistor structures, wherein partially removing the high-K dielectric layer may include a planarization process.

FIG. 3A shows a non-volatile memory structure 112 of a semiconductor substrate arrangement 100 (e.g. to be disposed over the semiconductor substrate 102 in the first area 103a) in a schematic cross sectional view, according to various embodiments. According to various embodiments, a layer stack 112 (in other words the non-volatile memory structure) may include a charge storage layer 312b and a control gate layer 312d disposed over the charge storage layer 312b. The layer stack 112 may be part of a non-volatile memory cell. The charge storage layer 312b may be separated, e.g. spatially and/or electrically, from the control gate layer 312d by an electrically insulating layer 312c, e.g. including at least one of an oxide layer, a nitride layer, an oxynitride layer, or a high-K material layer. Further, the charge storage layer 312b may be separated, e.g. spatially and/or electrically, from a semiconductor substrate 102 by an electrically insulating layer 312a, e.g. including at least one of an oxide layer, a nitride layer, an oxynitride layer, or a high-K material layer. Further, the control gate layer 312d may be covered by a hard mask layer 312e, e.g. including an oxide or a nitride hard mask.

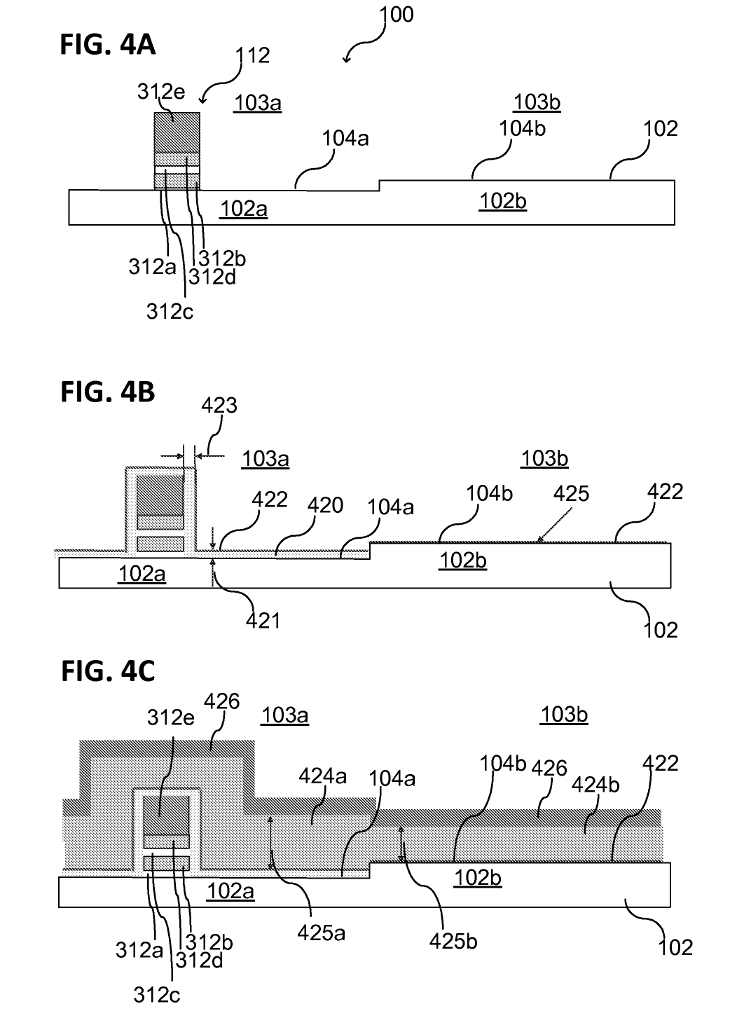

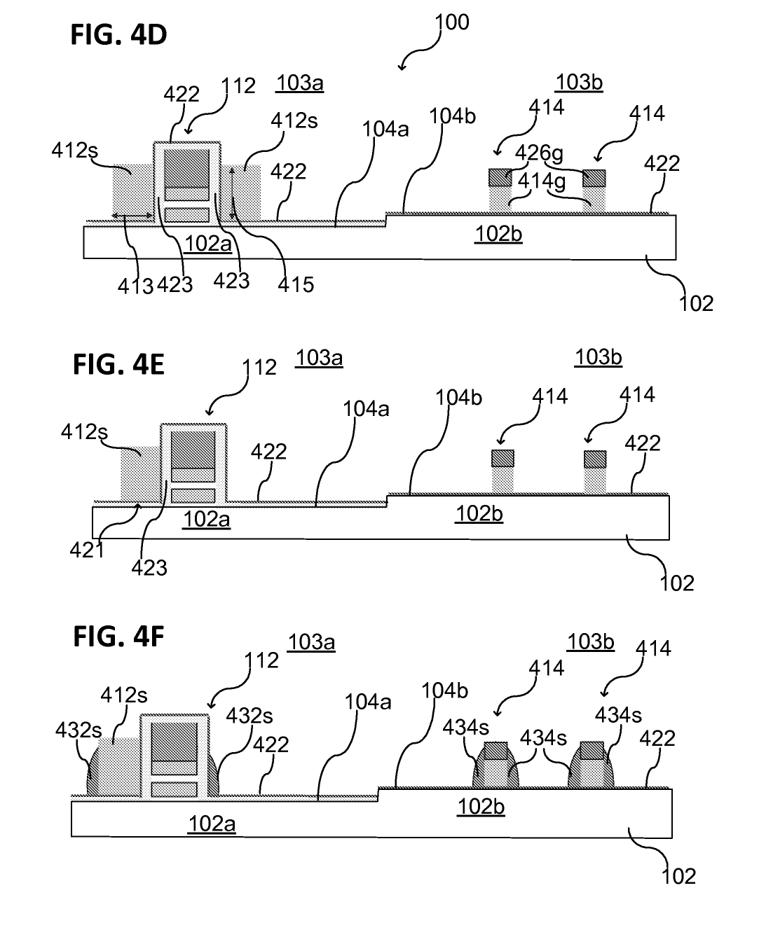

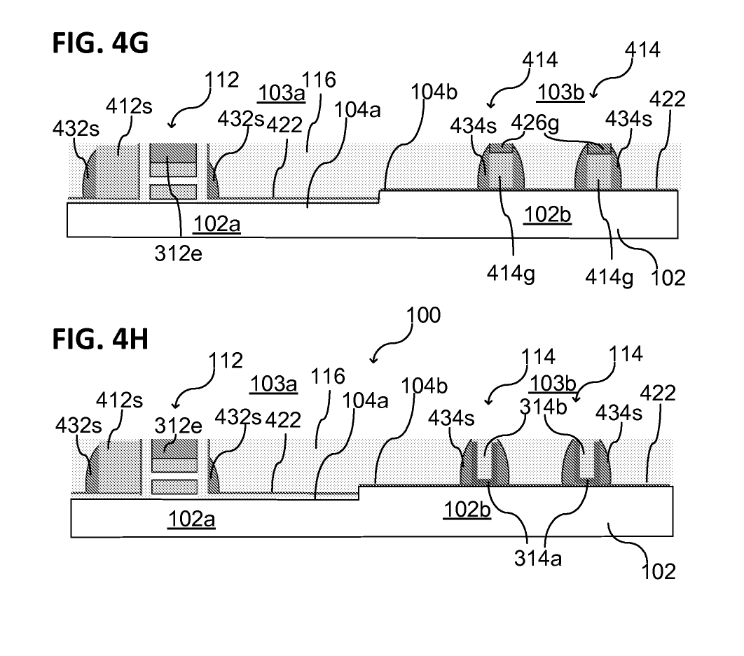

Further (cf. FIG. 4D), the non-volatile memory structure 112 may include a spacer as select gate, e.g. the spacer may include polysilicon. According to various embodiments, a non-volatile memory cell may be provided by at least the layer stack 112, the select gate, and corresponding doped regions in the semiconductor substrate 102.

According to various embodiments, each of the plurality of planar non-volatile memory structures 112 may be a planar floating gate transistor. Further, each planar floating gate transistor may include a polysilicon floating gate layer and a polysilicon control gate layer disposed over the polysilicon floating gate layer. Illustratively, a planar non-volatile memory structure 112 may include a so called double poly stack.

FIG. 3B to FIG. 3D show a planar transistor structure 114 of the semiconductor substrate arrangement 100 respectively in a schematic cross sectional view, according to various embodiments. Each of the plurality of planar transistor structures 114a may include a field effect transistor including a dielectric gate isolation layer 314a and an electrically conductive gate layer 314b disposed over the gate isolation layer 314a. The dielectric gate isolation layer 314a may include at least one of a dielectric oxide layer, a dielectric nitride layer, or a high-K dielectric material layer. According to various embodiments, the electrically conductive gate layer 314b may include at least one of a doped semiconductor layer or a metal layer.

According to various embodiments, as illustrated in FIG. 3C, the electrically conductive gate layer may include a metal layer 314b and an additional metal layer 314c below the metal layer 314b, wherein the additional metal of the additional metal layer 314c is in direct contact with a high-K dielectric material of the dielectric gate isolation layer 314a. The additional metal of the additional metal layer 314c may be configured to adapt the work function of the high-K dielectric material, e.g. a first additional metal may be used for providing p-channel metal-oxide-semiconductor field-effect transistors (p-channel MOSFETs) and a second additional metal different from the first additional metal may be used for providing n-channel metal-oxide-semiconductor field-effect transistors (n-channel MOSFETs).

According to various embodiments, the dielectric gate isolation layer 314a may include a silicon oxide layer 314d and a high-K dielectric material layer 314a disposed over the silicon oxide layer 314d. Further, the electrically conductive gate layer 314b may include a metal layer 314b and an additional metal layer 314c disposed between the metal layer 314b and the high-K dielectric material layer 314a, as illustrated in FIG. 3D.

Various modifications and/or configurations of the semiconductor substrate arrangement 100 and details referring to the NVM structures 112 and the planar transistor structures 114 are described in the following, wherein the features and/or functionalities described with reference to FIGS. 1A to 3D may be included analogously. Further, the features and/or functionalities described in the following may be included in the semiconductor substrate arrangement 100 or may be combined with the semiconductor substrate arrangement 100, as described with reference to FIGS. 1A to 3D.

As described in further detail below, according to various embodiments, embedding the NVM structures 112 may include at least one of the following boundary conditions: the NVM cell may be integrated before the high-K metal gate (high-K/MG) sequence is carried out to avoid thermally and/or chemically induced modifications of the sensitive high-K layer; the different gate-stack heights of the logic transistor 114 and the NVM structure 112 may require a planar topology due to CMP processes used in the high-K/MG sequence, which may be achieved by a reduced surface level 104a in the NVM area 103a.

Further, in case of a three poly NVM cell, a single polysilicon layer (referred to as third poly or poly3) may be used as both select gate of the NVM structures 112 in the first area 103a and dummy gate for the transistor structures 114 in the second area 103b for reducing the complexity of the processing. Further, in case the NVM cell 112 is a double stack cell (e.g. a uniform channel program (UCP) flash memory cell) a single polysilicon layer (referred to as second poly or poly2) may be used as both the control gate of the NVM structures 112 in the first area 103a and dummy gate for the transistor structures 114 in the second area 103b.

Conventionally, the NVM structures 112 and the logic transistors 114 on a single chip may be processed in the same technology with similar stack heights. According to various embodiments, NVM cells may be embedded into high-K/MG CMOS. Illustratively, the NVM cells or the NVM structures 112 of the NVM cells may include an ONO (oxide-nitride-oxide) interpoly-dielectric and a floating gate with relatively large thickness (e.g. with a thickness in the range from about 15 nm to about 35 nm), to provide a stable (reliable) NVM cell. Using a floating gate with a reduced thickness (e.g. less than about 10 nm) may be possible if the resulting loss of the capacitive coupling between floating gate and control gate may be compensated by using a high-K material instead of the ONO stack between the floating gate and control gate. However, this would lead to a higher leakage current through the high-K layer and, therefore, to retention failures.

Illustratively, instead of reducing the height of the NVMs cell and therefore decreasing the reliability of the NVMs cell as well, the topology may be compensated by a lower substrate surface level 104a in the area 103a for the NVM cells (also referred to as double poly area, high voltage area or mid voltage area).

According to various embodiments, the substrate surface level 104a may be reduced by removing substrate material in the NVM area 103a by etching, e.g. by reactive ion etching, for example in silicon bulk technology. Further, the substrate surface level 104a may be reduced by local oxidation of silicon (LOCOS) in the NVM area 103a and, subsequently, by an oxide etching (e.g. by reactive ion etching) of the generated silicon oxide in the NVM area 103a. According to various embodiments, in case the semiconductor substrate 102 is an SOI substrate, the substrate surface level 104a may be reduced by removing the semiconductor body (e.g. the silicon or silicon/germanium body over the buried insulator layer) in the NVM area 103a by etching (e.g. by reactive ion etching) and, subsequently, by removing the buried insulator layer (e.g. the buried oxide layer) by etching, e.g. by wet etching. According to various embodiments, the semiconductor substrate 102 may be annealed after an etch process has been carried out.

Alternatively, the substrate surface level 104b may be increased in the logic area 103b (also referred to as low voltage CMOS area), e.g. by selective epitaxy.

According to various embodiments, different shallow trench isolation (STI) processes may be carried out in the NVM area 103a and in the logic area 103b. According to various embodiments, a shallow trench (e.g. with a depth of about 350 nm) with relaxed pitch may be provided in the NVM area 103a (in other words in the high voltage area 103a). According to various embodiments, a shallow trench (e.g. with a depth of about 270 nm) with aggressive pitch may be provided in the logic area 103b (in other words in the low voltage area 103b). According to various embodiments, the STI trenches may have a width in the range from about 25 nm to about 50 nm. According to various embodiments, a deep trench may be used for electrically isolating p-wells and n-wells for back-biasing. According to various embodiments, a deep trench or a deep trench structure may be provided in the NVM area 103a.

According to various embodiments, high voltage structures, e.g. input/output structures, may be also provided within an area 103a with reduced surface level 104a.

In the following, FIGS. 4A to 4H show a semiconductor substrate arrangement 100 at various stages during processing respectively in a schematic cross sectional view, according to various embodiments. As illustrated in FIG. 4A, at least one first layer stack 112 (e.g. an NVM gate stack or an NVM structure 112) may be provided in the first area 103a, e.g. over the first region 102a of the semiconductor substrate 102. As already described, the NVM structure 112 may be provided at a first level 104a. The NVM structure 112 may include for example a first electrically insulating layer 312a (e.g. a tunnel oxide), a charge storage layer 312b (e.g. a floating gate) disposed over the first electrically insulating layer 312a, a second electrically insulating layer 312c (e.g. an ONO layer stack including a first oxide layer, a nitride layer over the first oxide layer, and a second oxide layer over the nitride layer) disposed over the charge storage layer 312b, a control gate layer 312d (e.g. a control gate) disposed over the second electrically insulating layer 312c, and a hard mask layer 312e (e.g. an oxide or a nitride, which may be for example selectively etchable with respect to silicon) disposed over the control gate layer 312d.

The control gate layer 312d and the charge storage layer 312b may include for example polysilicon, e.g. a first polysilicon layer 312b (also referred to as poly1) may provide the charge storage layer 312b and a second polysilicon layer 312d (also referred to as poly2) may provide the control gate layer 312d. According to various embodiments, the control gate 312d may have a thickness of about 25 nm. Further, the floating gate 312b may have a thickness of about 25 nm. According to various embodiments, the ONO layer stack 312c (also referred to as vertical interpoly oxide-nitride-oxide) may have a thickness of about 15 nm. According to various embodiments, the tunnel oxide 312a may have a thickness of about 10 nm, e.g. a thickness in the range from about 7 nm to about 12 nm. According to various embodiments, the hard mask 312e may have a thickness of about 75 nm before planarizing (cf. FIGS. 4A to 4F) and a thickness in the range from about 5 nm to about 25 nm after planarizing (cf. FIGS. 4G and 4H). According to various embodiments, after planarizing the NVM structure 112 may have a height in the range from about 75 nm to about 100 nm, e.g. in the range from about 80 nm to about 100 nm. According to various embodiments, the transistor structure to be formed in the second area 103b may have a height of about 50 nm. In this case, the step height between the first level 104a and the second level 104b may be for example in the range from about 25 nm to about 50 nm, e.g. in the range from about 30 nm to about 50 nm.

According to various embodiments, the double stack 312b, 312d may be integrated in the first area 103a before the transistors in the second area 103b are processed. The double stack 312b, 312d may be patterned by the hard mask 312e.

As illustrated in FIG. 4B, a lateral interpoly oxide 423 and a select gate oxide 421 may be provided in the first area 103a and a gate oxide 425 may be provided in the second area 103b. The gate oxide 425 (also referred to as low voltage gate oxide) in the second area 103b may be for example a pre-oxide for a dummy gate and may be provided by depositing (e.g. conformally depositing, e.g. by atomic layer deposition, ALD, or low pressure chemical vapor deposition, LPCVD) a gate oxide layer 422 over the semiconductor substrate 102. The lateral interpoly oxide 423 may be provided for example by a 3 nm side wall oxide, a 20 nm high temperature oxide and by the gate oxide layer 422. The select gate oxide 421 may be provided for example by a 3 nm side wall oxide, a 5 nm high temperature oxide and by the gate oxide layer 422.

As illustrated in FIG. 4C, a first region 424a of a third polysilicon layer (also referred to as poly3) may be provided in the first area 103a and a second region 424b of the third polysilicon layer may be provided in the second area 103b (the polysilicon regions 424a, 424b may be referred to as third polysilicon layer or poly3). According to various embodiments, a third polysilicon layer 424a, 424b may be used for both providing the select gate 412s in the first area 103a and a dummy gate 414g of a dummy transistor structure 414 in the second area 103b (cf. FIG. 4D). Further, any other transistor structure 414 may be provided in the second area 103b by the second region 424b of the third polysilicon layer.

The select gate 412s may require a select gate length 413 of about 100 nm and the dummy gate 414g may require a height of about 50 nm (cf. FIG. 4D), according to various embodiments. Therefore, according to various embodiments, the first region 424a of the third polysilicon layer in the first area 103a may be formed with a greater thickness than the second region 424b of the third polysilicon layer in the second area 103b. The first region 424a of the third polysilicon layer in the first area 103a may have a thickness 425a in the range from about 80 nm to about 100 nm and the second region 424b of the third polysilicon layer in the second area 103b may have a thickness 425b of about 50 nm. According to various embodiments, the third polysilicon layer may be deposited over the semiconductor substrate 102 having a thickness 425a in the range from about 80 nm to about 100 nm, wherein the third polysilicon layer may be partially removed (e.g. by etching) in the second area 103b to provide the second region 424b of the third polysilicon layer in the second area 103b with the thickness 425b of about 50 nm. Alternatively, the third polysilicon layer may be deposited by more than one layering process, e.g. a first polysilicon sublayer may be deposited over the semiconductor substrate 102 with a thickness in the range from about 30 nm to about 50 nm, the first polysilicon sublayer may be removed in the second area 103b but may remain in the first area 103a, and a second polysilicon sublayer may be deposited over the semiconductor substrate 102 with a thickness of about 50 nm therefore providing the first region 424a of the third polysilicon layer in the first area 103a with a thickness 425a in the range from about 80 nm to about 100 nm and the second region 424b of the third polysilicon layer in the second area 103b with a thickness 425b of about 50 nm.

Further, as illustrated in FIG. 4C, a hard mask layer 426 may be deposited over the third polysilicon layer 424a, 424b. The hard mask layer 426 may be for example selectively etchable compared to polysilicon. The hard mask layer 426 may include a nitride, e.g. silicon nitride or titanium nitride, and/or an oxide, e.g. silicon oxide.

As illustrated in FIG. 4D, according to various embodiments, the hard mask layer 426 may be used to pattern the third polysilicon layer 424a, 424b. Thereby, select gate structures 412s may be provided in the first area 103a and the dummy transistor structures 414 (or any other transistor structures 414) may be provided in the second area 103b. According to various embodiments, respectively two select gate structures 412s may be formed respectively adjacent to the first layer stack 112, wherein at least one of the two select gate structures 412s may be used as select gate 412s for the respective NVM structure 112 (cf. FIG. 4E). In other words, at least one select gate 412s may be part of the NVM cell. According to various embodiments, the two select gate structures 412s adjacent to the first layer stack 112 may be formed as sidewall spacers adjacent to the first layer stack 112, wherein, for example, the dummy gates 414g of the dummy transistor structures 414 in the second area 103b may remain covered with hard mask material 426g from the hard mask layer 426.

According to various embodiments, the select gate 412s may have a gate length 413 of about 100 nm, e.g. in the range from about 50 nm to about 200 nm. Further, the select gate 412s may have a gate height 415 of about 100 nm, e.g. in the range from about 80 nm to about 120 nm. According to various embodiments, the upper surface of the select gate 412s may be at a higher level than the upper surface of the dummy gates 414g of the dummy transistor structure 414.

According to various embodiments, one of the two select gate structures 412s adjacent to the first layer stack 112 may be removed, e.g. by etching, as for example illustrated in FIG. 4E. The select gate 412s may be electrically isolated from the first layer stack 112 by the lateral interpoly oxide 423 and, further, the select gate 412s may be electrically isolated from the first substrate region 102a by the select gate oxide 421.

As illustrated in FIG. 4F, according to various embodiments, a further spacer structure 432s, 434s may be utilized for assisting an ion implantation process, and after an activation of the implanted ions, e.g. by annealing, a desired doping (e.g. doping concentration and spatial doping distribution) is provided in the semiconductor substrate 102. The further spacer structures 432s, 434s may allow an LDD doping before the further spacer structures 432s, 434s are provided and an HDD doping after the further spacer structures 432s, 434s are formed over the semiconductor substrate 102. According to various embodiments, the further spacer structures 432s, 434s may include sidewall spacers 434s at the respective sidewalls of the dummy transistors structures 414 and sidewall spacers 432s at the respective sidewalls of the NVM structures 112 or the NVM cell, wherein the NVM cell may include the first layer stack 112 and the select gate 412s. According to various embodiments, each of the dummy transistors structures 414 may include a second layer stack 414.

As illustrated in FIG. 4G, according to various embodiments, an interlayer dielectric 116 may be deposited over the semiconductor substrate 102, the interlayer dielectric 116 covering and/or laterally surrounding the NVM structures 112 (or the NVM cell) and the dummy transistors structures 414. The interlayer dielectric 116 may for example cover the select gate 412s of the NVM cell in the first area 103a.

FIG. 4G illustrates a semiconductor substrate arrangement 100 during processing, e.g. after a planarization has been carried out. According to various embodiments, a CMP process may be used to expose a flat surface for the structures provided on the semiconductor substrate 102. During the CMP process, the hard mask layer 312e or hard mask region 312e of the first layer stack 112 (in other words of the NVM structure 112) may be partially removed and/or the hard mask layer 312e or hard mask region 312e of the first layer stack 112 may be at least partially exposed. During the CMP process, the hard mask layer covering the dummy gates 414g of the dummy transistor structures 414 in the second area 103b may be partially removed and/or the hard mask layer 426g covering the dummy gates 414g of the dummy transistor structures 414 in the second area 103b may be at least partially exposed.

According to various embodiments, since the first layer stack 112 (in other words the NVM structure 112 or the NVM cell) is formed in the first area 103a at a lower level than the dummy transistor structures 414, the CMP process can be carried out without damaging the first layer stack 112, e.g. without removing or partially removing the control gate layer 312d of the first layer stack 112 by the CMP process and/or without completely removing the hard mask region 312e of the first layer stack 112, as illustrated for example in FIG. 4G. According to various embodiments, the CMP process may be required for forming a plurality of transistor structures 114 (as described for example in FIGS. 3B to 3D) from the dummy transistor structures 414 in the second area 103b. According to various embodiments, the hard mask region 312e of the first layer stack 112 may be referred to as control gate etch hard mask and the hard mask layer 426g covering the dummy gates 414g of the dummy transistor structures 414 may be referred to as polyconductor etch hard mask, since the third layer 424a, 424b may be referred to as polyconductor layer 424a, 424b (cf. FIG. 4C). Therefore, the dummy transistor structures 414 may include a polyconductor region 414g respectively formed from the polyconductor layer 424a, 424b.

According to various embodiments, one or more CMP processes may be required for forming a plurality of transistor structures 114, e.g. a plurality of high-K metal gate transistors (as described for example in FIGS. 3B to 3D) from the dummy transistor structures 414 in the second area 103b, as illustrated for example in FIG. 4H, according to various embodiments.

According to various embodiments, the hard mask layer 426g covering the dummy gates 414g of the dummy transistor structures 414 may be (e.g. selectively) removed, e.g. by etching, e.g. by reactive ion etching. After the hard mask layer 426g of the dummy transistor structures 414 has been removed, the dummy gates 414g of the dummy transistor structures 414 may be (e.g. selectively) removed, e.g. by etching, e.g. by wet etching or reactive ion etching. According to various embodiments, the further spacer structures 434s at the sidewalls of the dummy transistor structures 414 may be completely removed, partially removed, or may remain unchanged during the plurality of transistor structures 114 are formed from the dummy transistor structures 414 in the second area 103b.

According to various embodiments, the NVM structures 112 or the NVM cells in the first area 103a of the semiconductor substrate arrangement 100 may be temporarily covered with masking material during the plurality of transistor structures 114 are formed from the dummy transistor structures 414 in the second area 103b. Illustratively, the plurality of transistor structures 114 are formed from the dummy transistor structures 414 in the second area 103b so that the NVM structures 112 or the NVM cells in the first area 103a are not affected.

According to various embodiments, after the dummy gates 414g of the dummy transistor structures 414 have been removed, the resulting free space may be partially filled with a high-K material providing a high-K gate isolation layer 314a and partially filled with one or more metals providing a metal gate 314b over the high-K gate isolation layer 314a.

Illustratively, after the NVM structures 112 (or in other words the NVM cells) are provided over the semiconductor substrate 102 in the first area 103a, a plurality of high-K metal gate transistors 114 (as described for example in FIGS. 3B to 3D) are formed from the dummy transistor structures 414 in the second area 103b in gate last technology, as illustrated for example in FIG. 4H, according to various embodiments. Thereby, the polyconductor 414g of the dummy transistor structures 414 may be replaced by a high-K metal gate structure 114, as described before.

According to various embodiments, the high-K gate isolation layer 314a of the transistor structures 114 may be formed by depositing a high-K material layer over the semiconductor substrate 102 (e.g. conformally using ALD or LPCVD) and by a CMP process carried out subsequently. According to various embodiments, the one or more metals providing a metal gate 314b of the transistor structures 114 may be formed by depositing one or more metal layers over the semiconductor substrate 102 (e.g. conformally using ALD or LPCVD) and by at least one CMP process carried out subsequently.

According to various embodiments, the transistor structures 114 may include a metal layer 314b and an additional metal layer 314c below the metal layer 314b, wherein the additional metal of the additional metal layer 314c is in direct contact with a high-K dielectric material of the dielectric gate isolation layer 314a cf. for example FIG. 3C). The additional metal 314c may be configured to adapt the work function of the high-K dielectric material 314a (which is in contact with the additional metal 314c) as desired.

According to various embodiments, as illustrated for example in FIG. 4H, the semiconductor substrate arrangement 100 may have planar top surface, e.g. due to the at least one CMP process applied during processing the semiconductor substrate arrangement 100, so that a passivation layer and/or a metallization layer can be formed over the planar top surface. According to various embodiments, a passivation layer and/or a metallization layer may be provided over the plurality of planar non-volatile memory structures 112 and the planar transistor structures 114, wherein the semiconductor substrate arrangement 100 may include a planar interface between the passivation layer and the plurality of planar non-volatile memory structures 112 and the planar transistor structures 114 and/or between the metallization layer and the plurality of planar non-volatile memory structures 112 and the planar transistor structures 114.

According to various embodiments, a semiconductor substrate arrangement may include: a semiconductor substrate defining a first area at a first level and a second area next to the first area at a second level, wherein the first level is lower than the second level; a plurality of planar non-volatile memory structures disposed over the semiconductor substrate in the first area; and a plurality of planar transistor structures disposed over the semiconductor substrate in the second area.

According to various embodiments, both levels may be planar and parallel to each other. According to various embodiments, the semiconductor substrate may include at least one step providing at least two plateaus at different height levels. As illustrated for example in FIG. 1C, the semiconductor substrate 102 may include a step 111c providing two plateaus 104a, 104b at different height levels.

According to various embodiments, the first area and the second area may be adjacent to each other.

According to various embodiments, the semiconductor substrate arrangement may include a passivation layer disposed over the plurality of planar non-volatile memory structures and the planar transistor structures, wherein a planar interface may be provided between the passivation layer and the plurality of planar non-volatile memory structures and the planar transistor structures, e.g. by at least one planarization process carried out during processing the semiconductor substrate arrangement.

According to various embodiments, the semiconductor substrate may include silicon or may be a silicon substrate. According to various embodiments, the semiconductor substrate may include or may be a wafer, e.g. a silicon wafer or a silicon on insulator wafer.

According to various embodiments, the semiconductor substrate may include a plurality of doping regions, e.g. wells, e.g. LDD and/or HDD doped regions, e.g. p-type and/or n-type doped regions (so called source/drain regions), to provide functioning planar non-volatile memory structures and functioning planar transistor structures.

According to various embodiments, the semiconductor substrate may have a first thickness in the first area and a second thickness greater than the first thickness in the second area. Illustratively, a chip or a wafer may have at least two substrate regions with different thicknesses.

According to various embodiments, the semiconductor substrate may include a buried silicon oxide layer in the second area. According to various embodiments, the semiconductor substrate may be free from the buried silicon oxide layer in the first area. Illustratively, the different height levels of the semiconductor substrate arrangement may be provided by removing a buried oxide layer and the semiconductor layer over the buried oxide layer in the first area. Illustratively, the different height levels of the semiconductor substrate arrangement may be provided by removing a buried silicon oxide layer and the silicon over the buried silicon oxide layer in the first area.

According to various embodiments, the first area may extend over more than 20% of a front side of the semiconductor substrate and wherein the second area may extend over more than 20% of the front side of the semiconductor substrate. Illustratively, the area fraction of the first area and the area fraction of the second area may be large compared to the total active area of the semiconductor substrate.

According to various embodiments, the semiconductor substrate arrangement may further include: an additional layer disposed over the plurality of planar non-volatile memory structures and the plurality of planar transistor structures, wherein the additional layer has a planar interface plane facing the plurality of planar non-volatile memory structures and the plurality of planar transistor structures.

According to various embodiments, the additional layer may include at least one of a passivation layer or a metallization layer. Further, the metallization layer may electrically contact the plurality of planar non-volatile memory structures and the plurality of planar transistor structures.

According to various embodiments, each of the plurality of planar non-volatile memory structures may have a first height; and each of the plurality of planar transistor structures may have a second height, wherein the second height is less than the first height.

According to various embodiments, each of the plurality of planar non-volatile memory structures may include a layer stack. According to various embodiments, the respective layer stack of the planar non-volatile memory structure may include a charge storage layer and a control gate layer disposed over the charge storage layer. According to various embodiments, at least one dielectric layer may be disposed between the charge storage layer and the control gate layer. According to various embodiments, at least one dielectric layer may be disposed between the charge storage layer and the semiconductor substrate in the first area.

According to various embodiments, a top surface of the control gate layer (facing away from the semiconductor substrate) and a top surface of the semiconductor substrate (in other words the surface of the semiconductor substrate at the first level) in the first chip region (facing the control gate layer) may define the height of the non-volatile memory structure.

According to various embodiments, each of the plurality of planar non-volatile memory structures may include a planar floating gate transistor.

According to various embodiments, each planar floating gate transistor may include a polysilicon floating gate layer and a polysilicon control gate layer disposed over the polysilicon floating gate layer. According to various embodiments, at least one dielectric layer (also referred to as interpoly-dielectric) may be disposed between the polysilicon floating gate layer and the polysilicon control gate layer. According to various embodiments, at least one dielectric layer may be disposed between the polysilicon floating gate layer and the semiconductor substrate in the first area.

According to various embodiments, the polysilicon floating gate layer, the polysilicon control gate layer, the at least one dielectric layer disposed between the polysilicon floating gate layer and the polysilicon control gate layer, and the at least one dielectric layer disposed between the polysilicon floating gate layer and the semiconductor substrate in the first area may define the height of the respective planar non-volatile memory structure (or in other words the height of the respective planar floating gate transistor).

According to various embodiments, each planar floating gate transistor may include a polysilicon select gate.

According to various embodiments, each of the plurality of planar transistor structures may include a field effect transistor.

According to various embodiments, each field effect transistor may include a dielectric gate isolation layer and an electrically conductive gate layer disposed over (e.g. in direct physical contact with) the gate isolation layer.

According to various embodiments, a top surface of the electrically conductive gate layer (facing away from the semiconductor substrate) and a top surface of the semiconductor substrate (in other words the surface of the semiconductor substrate at the second level) in the second chip region (facing the electrically conductive gate layer) may define the height of the transistor structure.

According to various embodiments, the dielectric gate isolation layer of the field effect transistor may include at least one layer of the following group of layers, the group consisting of: a dielectric oxide layer; a dielectric nitride layer; a high-K dielectric material layer. According to various embodiments, the dielectric gate isolation layer of the field effect transistor may include an oxide liner below a high-K dielectric material layer.

According to various embodiments, the electrically conductive gate layer of the field effect transistor may include at least one of a doped semiconductor layer or a metal layer.

According to various embodiments, the dielectric gate isolation layer and the electrically conductive gate layer may define the height of the respective transistor structure (or in other words the height of the respective planar field effect transistor).

According to various embodiments, the semiconductor substrate arrangement may further include a plurality of first trench isolation structures in the first area extending into the semiconductor substrate for laterally electrically isolating the plurality of planar non-volatile memory structures from each other. According to various embodiments, the semiconductor substrate arrangement may further include a plurality of second trench isolation structures in the second area extending into the semiconductor substrate with a second depth for laterally electrically isolating the plurality of planar transistor structures from each other. Further, according to various embodiments, the first depth may be greater than the second depth. According to various embodiments, the first trench isolation structures and the second trench isolation structures may be shallow trench isolations. According to various embodiments, each trench isolation structure may include a trench filled with electrically insulating material.

According to various embodiments, the semiconductor substrate arrangement may further include a plurality of first source regions and a plurality of first drain regions in the first area for operating the plurality of planar non-volatile memory structures. According to various embodiments, the semiconductor substrate arrangement may further include a plurality of second source regions and a plurality of second drain regions in the second area for operating the plurality of planar transistor structures.

According to various embodiments, the semiconductor substrate arrangement 100 may be a semiconductor device, e.g. a chip or a die. According to various embodiments, the semiconductor substrate arrangement 100 may be a semiconductor wafer. According to various embodiments, the semiconductor wafer may include a plurality of chip areas, wherein each chip area may include at least one NVM area for accommodating a plurality of non-volatile memory cells at a first level and at least one logic area next to the at least one NVM area for accommodating a plurality of transistors at a second level higher than the first level.

According to various embodiments, a semiconductor device may include: a semiconductor substrate having at least one first area for accommodating a plurality of non-volatile memory cells at a first level and at least one second area next to the at least one first area for accommodating a plurality of transistors at a second level higher than the first level; the plurality of non-volatile memory cells formed over the semiconductor substrate in the at least one first area, wherein each of the plurality of non-volatile memory cells has a first height; and the plurality of transistors formed over the semiconductor substrate in the at least one second area, wherein each of the plurality of transistors has a second height, wherein the second height is less than the first height.

According to various embodiments, a method for processing a wafer may include: forming a plurality of non-volatile memory structures over a first area of the wafer, wherein the first area has a first level; forming a plurality of transistor structures over a second area of the wafer, wherein the second area has a second level higher than the first level; and planarizing the wafer to provide a flat surface or interface over plurality of transistor structures and the plurality of non-volatile memory structures.

According to various embodiments, forming the plurality of non-volatile memory structures may include forming a plurality of first layer stacks, each of the first layer stacks including a charge storage layer and a control gate layer disposed over the charge storage layer. According to various embodiments, forming the plurality of transistor structures may include forming a plurality of second layer stacks, each of the second layer stacks including a dielectric gate isolation layer and a metal gate layer disposed over the gate isolation layer. Further, according to various embodiments, the plurality of first layer stacks may be formed before the plurality of second layer stacks is formed. Further, according to various embodiments, each of the plurality of first layer stacks may have a first height and each of the plurality of second layer stacks second height less than the first height.

According to various embodiments, a semiconductor substrate may include: a first substrate region having a first level and a second substrate region next to the first substrate region having a second level higher than the first level; a plurality of floating gate transistor structures formed in the first substrate region, wherein each of the plurality of floating gate transistor structures has a first height; a plurality of high-K metal gate transistor structures formed in the second substrate region, wherein each of the plurality of high-K metal gate transistor structures has a second height less than the first height.

According to various embodiments, a chip may include: a substrate having a first area for accommodating a plurality of non-volatile memory structures at a first level and a second area next to the first area for accommodating a plurality of transistor structures at a second level higher than the first level; the plurality of non-volatile memory structures formed over the semiconductor substrate in the first area, wherein each of the plurality of non-volatile memory structures has a first height; and the plurality of transistor structures formed over the semiconductor substrate in the second area, wherein each of the plurality of transistor structures has a second height, wherein the second height is less than the first height.

According to various embodiments, a semiconductor device may include: a semiconductor substrate defining at least one first area for accommodating a plurality of transistor structures (e.g. high voltage transistors) at a first level and at least one second area next to the at least one first area for accommodating a plurality of high-K metal gate transistors at a second level higher than the first level; the plurality of transistor structures formed over the semiconductor substrate in the at least one first area, wherein each of the plurality of transistor structures has a first height; and the plurality of high-K metal gate transistors formed over the semiconductor substrate in the at least one second area, wherein each of the plurality of high-K metal gate transistors has a second height, wherein the second height is less than the first height.

According to various embodiments, a method for processing a wafer may include: at least one of removing a portion of the wafer in a first area of the wafer or covering the wafer with at least one layer in a second area of the wafer to provide a first level in the first area and a second level higher than the first level in the second area; forming a plurality of non-volatile memory structures over the first area; forming a plurality of transistor structures over the second area; and planarizing the surface of the wafer after at least partially (e.g. completely) forming the plurality of non-volatile memory structures.

According to various embodiments, forming the plurality of non-volatile memory structures may include an annealing at a temperature of equal to or greater than about 500° C., e.g. an annealing at a temperature in the range from about 500° C. to about 800° C. The annealing may be used for example to activate implanted doping material.

According to various embodiments, forming the plurality of transistor structures may include forming a plurality of high-K metal gate transistors in gate last processing technology.

According to various embodiments, a method for processing a wafer may include: at least one of removing a portion of the wafer in a first area of the wafer or covering the wafer with at least one layer in a second area of the wafer to provide a first level in the first area and a second level higher than the first level in the second area; forming a plurality of non-volatile memory structures over the first area; and, e.g. subsequently, and forming a plurality of transistor structures over the second area, wherein each of the plurality of transistor structures has a second height less than the first height.

According to various embodiments, forming the plurality of transistor structures may include at least one planarization process, e.g. chemical mechanical polishing (CMP).

According to various embodiments, a method for processing a semiconductor substrate may include: forming a plurality of non-volatile memory structures over the semiconductor substrate in a first area of the semiconductor substrate, wherein the first area has a first level; forming a plurality of transistor structures over the semiconductor substrate in a second area of the semiconductor substrate, wherein the second area has a second level higher than the first level, wherein forming the plurality of transistor structures includes forming at least one electrically conductive layer and partially removing the at least one electrically conductive layer so that remaining portions of the at least one electrically conductive layer form a gate region for each of the plurality of transistor structures and such that the remaining portions are electrically separated from each other, wherein partially removing the at least one electrically conductive layer includes at least one planarization process.

According to various embodiments, the at least one electrically conductive layer may be at least one metal layer. According to various embodiments, the electrically conductive layer may fill a plurality of trench structures provided in the second area. The plurality of trench structures may be formed by removing a dummy gate from a dummy transistor structure in the second area.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A semiconductor substrate arrangement comprising:
a semiconductor substrate defining a first area at a first level and a second area next to the first area at a second level, wherein the first level is lower than the second level;
a plurality of planar non-volatile memory structures disposed over the semiconductor substrate in the first area; and
a plurality of planar transistor structures disposed over the semiconductor substrate in the second area.

2. The semiconductor substrate arrangement of claim 1,
wherein the semiconductor substrate comprises silicon.

3. The semiconductor substrate arrangement of claim 1,
wherein the semiconductor substrate has a first thickness defining the first area and a second thickness greater than the first thickness defining the second area.

4. The semiconductor substrate arrangement of claim 1,
wherein the semiconductor substrate comprises a buried silicon oxide layer in the second area.

5. The semiconductor substrate arrangement of claim 4,
wherein the semiconductor substrate is free from the buried silicon oxide layer in the first area.

6. The semiconductor substrate arrangement of claim 1, further comprising:
an additional layer disposed over the plurality of planar non-volatile memory structures and the plurality of planar transistor structures, wherein the additional layer has a planar interface plane facing the plurality of planar non-volatile memory structures and the plurality of planar transistor structures.

7. The semiconductor substrate arrangement of claim 6,
wherein the additional layer comprises at least one of a passivation layer or a metallization layer.

8. The semiconductor substrate arrangement of claim 1,
wherein each of the plurality of planar non-volatile memory structures has a first height; and
wherein each of the plurality of planar transistor structures has a second height, wherein the second height is less than the first height.

9. The semiconductor substrate arrangement of claim 1,
wherein each of the plurality of planar non-volatile memory structures comprises a layer stack; the layer stack comprising a charge storage layer and a control gate layer disposed over the charge storage layer.

10. The semiconductor substrate arrangement of claim 1,
wherein each of the plurality of planar non-volatile memory structures comprises a planar floating gate transistor.

11. The semiconductor substrate arrangement of claim 10,
wherein each planar floating gate transistor comprises a polysilicon floating gate layer and a polysilicon control gate layer disposed over the polysilicon floating gate layer.

12. The semiconductor substrate arrangement of claim 1,
wherein each of the plurality of planar transistor structures comprises a field effect transistor.

13. The semiconductor substrate arrangement of claim 12,
wherein each field effect transistor comprises a dielectric gate isolation layer and an electrically conductive gate layer disposed over the gate isolation layer.

14. The semiconductor substrate arrangement of claim 13,
wherein the dielectric gate isolation layer comprises at least one layer of the following group of layers, the group consisting of:
a dielectric oxide layer;
a dielectric nitride layer;
a high-K dielectric material layer.

15. The semiconductor substrate arrangement of claim 11,
wherein the electrically conductive gate layer comprises at least one of a doped semiconductor layer or a metal layer.

16. The semiconductor substrate arrangement of claim 1, further comprising:
a plurality of first trench isolation structures in the first area extending into the semiconductor substrate for laterally electrically isolating the plurality of planar non-volatile memory structures from each other and a plurality of second trench isolation structures in the second area extending into the semiconductor substrate with a second depth for laterally electrically isolating the plurality of planar transistor structures from each other, wherein the first depth is greater than the second depth.

17. The semiconductor substrate arrangement of claim 1, further comprising:
a plurality of first source regions and a plurality of first drain regions in the first area for operating the plurality of planar non-volatile memory structures and a plurality of second source regions and a plurality of second drain regions in the second area for operating the plurality of planar transistor structures.

18. A semiconductor device comprising:
a semiconductor substrate defining at least one first area for accommodating a plurality of transistor structures at a first level and at least one second area next to the at least one first area for accommodating a plurality of high-K metal gate transistors at a second level higher than the first level;
the plurality of transistor structures formed over the semiconductor substrate in the at least one first area, wherein each of the plurality of transistor structures has a first height; and
the plurality of high-K metal gate transistors formed over the semiconductor substrate in the at least one second area, wherein each of the plurality of high-K metal gate transistors has a second height, wherein the second height is less than the first height.

19. A method for processing a semiconductor substrate, the method comprising:
forming a plurality of non-volatile memory structures over the semiconductor substrate in a first area defined by the semiconductor substrate, wherein the first area has a first level;
forming a plurality of transistor structures over the semiconductor substrate in a second area defined by the semiconductor substrate, wherein the second area has a second level higher than the first level,
wherein forming the plurality of transistor structures comprises forming at least one electrically conductive layer and partially removing the at least one electrically conductive layer so that remaining portions of the at least one electrically conductive layer form a gate region for each of the plurality of transistor structures and such that the remaining portions are electrically separated from each other, wherein partially removing the at least one electrically conductive layer comprises at least one planarization process.

20. The method of claim 19,
wherein the at least one electrically conductive layer is at least one metal layer.
